(19) United States
(12) Patent Application Publication
(10) Pub. No.: US 2012/0222728 A1
(43) Pub. Date: Sep. 6, 2012

(54) SOLAR CELL MODULE AND MANUFACTURING METHOD THEREOF

(76) Inventors: Hiroyuki NAKANISHI, Osaka-shi (JP); Seiji ISHIHARA, Osaka-shi (JP); Etsuko ISHIZUKA, Osaka-shi (JP)

(21) Appl. No.: 13/410,699

(22) Filed: Mar. 2, 2012

(30) Foreign Application Priority Data
Mar. 4, 2011 (JP) 2011-048335

(51) Int. Cl. H01L 31/048; H01L 31/18; H01L 31/05

(52) U.S. Cl. 136/251; 136/244; 438/66; 257/E31.117

(57) ABSTRACT

A solar cell module of the present invention is arranged such that is at least one of two-dimensionally arranged solar cells is positioned on an extended line of a boundary line between other adjacent solar cells. This makes it possible to provide a solar cell module which is less likely to be broken even if a bending stress and/or a twisting stress is applied, as compared to a conventional solar cell module.

This Nonprovisional application claims priority under 35 U.S.C. §119(a) on Patent Application No. 2011-048335 filed in Japan on Mar. 4, 2011, the entire contents of which are hereby incorporated by reference.

### TECHNICAL FIELD

The present invention relates to a solar cell module which includes a plurality of solar cells, and converts optical energy into electrical energy by use of the solar cells.

### BACKGROUND ART

Recently, photovoltaic power generation attracts attention from viewpoints of energy saving and energy creation, and residential household photovoltaic power generation systems etc. are becoming prevalent. Further, other than large stationary-type photovoltaic power generation systems, there proposed small portable photovoltaic power generation systems (see Patent Literatures 1 and 2 below, and Non-patent Literatures 1 and 2 below).

The conventional photovoltaic power generation systems each have a solar cell module with a plurality of solar cells. The following describes such a conventional solar cell module.

FIG. 18 is a plan view illustrating the conventional solar cell module. FIG. 19 is a side view illustrating the solar cell module in FIG. 18. FIG. 20 is a bottom view illustrating the solar cell module in FIG. 18.

In a solar cell module 400 illustrated in FIGS. 18 through 20, a plurality of back-side-electrode-type solar cells 401 which are arranged in a matrix pattern are provided on a upper surface of a circuit substrate 402 via a conductive joining material. Provided on each of the upper and lower surfaces of the circuit substrate 402 are wires and terminals (pads).

Each of the back-side-electrode-type solar cells 401 has, on its surface opposite to its light-receiving surface, a positive electrode terminal and a negative electrode terminal which are not illustrated. The back-side-electrode-type solar cells 401 are connected in, e.g., series via these terminals and via the wires etc. which are provided on the circuit substrate 402. Two wires are respectively led to the lower surface of the circuit substrate 402 via through holes 403 from back-side-electrode-type solar cells 401 located at both ends of a series circuit made up of the back-side-electrode-type solar cells 401.

Provided on the lower surface (the surface opposite to the surface on which the solar cells 401 are provided) of the circuit substrate 402 are a positive electrode terminal 404 and a negative electrode terminal 405 which are connected respectively with the two wires. Thus, the two liens led to the lower surface of the circuit substrate 402 via the through holes 403 are connected with the positive electrode terminal 404 and the negative electrode terminal 405, respectively.

FIG. 23 is a plan view illustrating another example of the conventional solar cell module. FIG. 24 is a side view illustrating the solar cell module in FIG. 23. FIG. 25 is a bottom view illustrating the solar cell module in FIG. 23. Solar cells of a solar cell module 500 illustrated in FIGS. 23 through 25 are double-sided electrode type solar cells 501.

A conductive section (corresponding to a binding section 22 in FIG. 26 of the present invention) provided on each of the double-sided electrode type solar cells 501 is connected, via metal wires 514, with a wire-connection terminal 513 provided on a circuit substrate 502. Two wires are respectively led to the lower surface of the circuit substrate 502 via through holes 503 from double-sided electrode type solar cells 501 located at both ends of a series circuit made up of the double-sided electrode type solar cells 501 which are connected in, e.g., series by the connection above via the metal wires 514. As illustrated in FIG. 25, the two wires are connected with a positive electrode terminal 504 and a negative electrode terminal 505 which are provided on the lower surface of the circuit substrate 502.

### CITATION LIST

### Patent Literatures

Patent Literature 1
Japanese Patent Application Publication, Tokukai, No. 2010-103441 A (Publication Date: May 6, 2010)

Patent Literature 2
Japanese Patent Application Publication, Tokukai, No. 2010-287795 A (Publication Date: Dec. 24, 2010)

### Non-Patent Literatures

Non-Patent Literature 1
Nikkei Electronics, Nikkei Business Publications, 2009-7-27, No. 1009, PP. 52-55 (Publication Date: Jul. 27, 2009)

Non-Patent Literature 2
Japanese Design Application Publication (Design Registration No. 1367985 (Issued Date: Aug. 24, 2009))

### SUMMARY OF INVENTION

### Technical Problem

In the conventional solar cell modules 400 and 500, the back-side-electrode-type solar cells 401 and the double-sided electrode type solar cells 501 (hereinafter, these solar cells are referred to as solar cells) are arranged so that a boundary line between adjacent solar cells and a boundary line between other adjacent solar cells are positioned on single straight lines H1, H2, and V1 through V8 (hereinafter, such straight lines are referred to as Line section; see FIGS. 18 and 23).

In such an arrangement, the Line sections have a lower stiffness as compared to areas of the solar cells 401 and 501. This leads to such a problem that in a case where a bending stress and a twisting stress are applied to the solar cell module 400 or 500, the solar cell module 400 or 500 is likely to be deformed at the Line sections, and if the stresses are large, the solar cell module 400 or 500 is bent or cracked at the Line sections.

The present invention was made in view of the problem. An object of the present invention is to provide a solar cell module which is less likely to be broken as compared to a conventional solar cell module even if the bending stress and the twisting stress are applied thereto.

### Solution to Problem

A solar cell module of the present invention includes a plurality of solar cells, the plurality of solar cells being two-dimensionally arranged, at least one of the plurality of solar cells being positioned on an extended line of a boundary line between solar cells adjacent to the at least one of the plurality of solar cells.

According to the arrangement, at least one of the plurality of solar cells is positioned on an extended line of a boundary line between solar cells adjacent to the at least one of the plurality of solar cells. This allows the solar cell module to have a structure difficult to bend and twist even if the bending stress and the twisting stress are applied to the extended line of the boundary line.

This makes it possible to decrease a possibility that the solar cell module is bent and cracked at the boundary line, as compared to such an arrangement that in a case where two adjacent solar cells are regarded as one pair, a boundary line between two solar cells in each of such pairs is located on a single straight line.

### Advantageous Effects of Invention

A solar cell module of the present invention includes a plurality of solar cells, the plurality of solar cells being two-dimensionally arranged, at least one of the plurality of solar cells being positioned on an extended line of a boundary line between solar cells adjacent to the at least one of the plurality of solar cells.

The arrangement allows the solar cell module to have a structure difficult to bend and twist even if the bending stress and the twisting stress are applied to an extended line of a boundary line of adjacent solar cells. This makes it possible to prevent the solar cell module from being bent and cracked at the boundary line. As a result, the solar cell module can have an increased stiffness.

### BRIEF DESCRIPTION OF DRAWINGS

FIG. 1 is a circuit diagram illustrating one example of a circuit configuration of a solar battery which includes a solar cell module of the present invention.

FIG. 2 is a plan view illustrating an appearance arrangement of Embodiment 1 of the solar cell module of the present invention.

FIG. 3 is a side view illustrating the solar cell module of Embodiment 1.

FIG. 4 is a bottom view illustrating the solar cell module of Embodiment 1.

FIG. 5 is a view illustrating one example of a wiring pattern on a circuit substrate.

FIG. 6 is an enlarged view of a comb-teeth wiring pattern section which constitutes the wiring pattern.

FIG. 7 is a plan view illustrating an appearance arrangement of Embodiment 2 of the solar cell module of the present invention.

FIG. 8 is a side view illustrating the solar cell module of Embodiment 2.

FIG. 9 is a bottom view illustrating the solar cell module of Embodiment 2.

FIG. 10 is a plan view illustrating an appearance arrangement of Embodiment 3 of the solar cell module of the present invention.

FIG. 11 is a side view illustrating the solar cell module of Embodiment 3.

FIG. 12 is a bottom view illustrating the solar cell module of Embodiment 3.

FIG. 13 is an enlarged view of a region enclosed by a dashed line indicated with an arrow Z in FIG. 10.

FIG. 14 is a view illustrating one example of a wiring pattern on a circuit substrate.

FIG. 15 is a view illustrating one example of how solar cells of the solar cell module of the present invention are positioned.

FIG. 16 is a view illustrating one example of how the solar cell module illustrated in FIG. 2 is deformed in a case where horizontal stresses F1 and F2 are applied.

FIG. 17 is a view illustrating one example of how the solar cell module illustrated in FIG. 10 is deformed in a case where horizontal stresses F1 and F2 are applied, and one example of how the solar cell module is deformed in a case where vertical stresses F3 and F4 are applied.

FIG. 18 is a plan view illustrating a conventional solar cell module.

FIG. 19 is a side view illustrating the solar cell module of FIG. 18.

FIG. 20 is a bottom view illustrating the solar cell module of FIG. 18.

FIG. 21 is an external view illustrating one example of a solar cell module (back-side-electrode-type solar cell) which is mounted on the solar cell modules of Embodiments 1 and 2.

FIG. 22 is a cross-sectional view illustrating a cross-section taken along a line B-B with arrows in FIG. 21.

FIG. 23 is a plan view illustrating another example of the conventional solar cell module.

FIG. 24 is a side view illustrating the solar cell module of FIG. 23.

FIG. 25 is a bottom view illustrating the solar cell module of FIG. 23.

FIG. 26 is an external view illustrating one example of a solar cell module (double-sided electrode type solar cell) which is mounted on the solar cell module of Embodiment 3.

FIG. 27 is a cross-sectional view illustrating a cross-section taken along a line C-C with arrows in FIG. 26.

FIG. 28 is a view illustrating steps of manufacturing the solar cell module.

### DESCRIPTION OF EMBODIMENTS

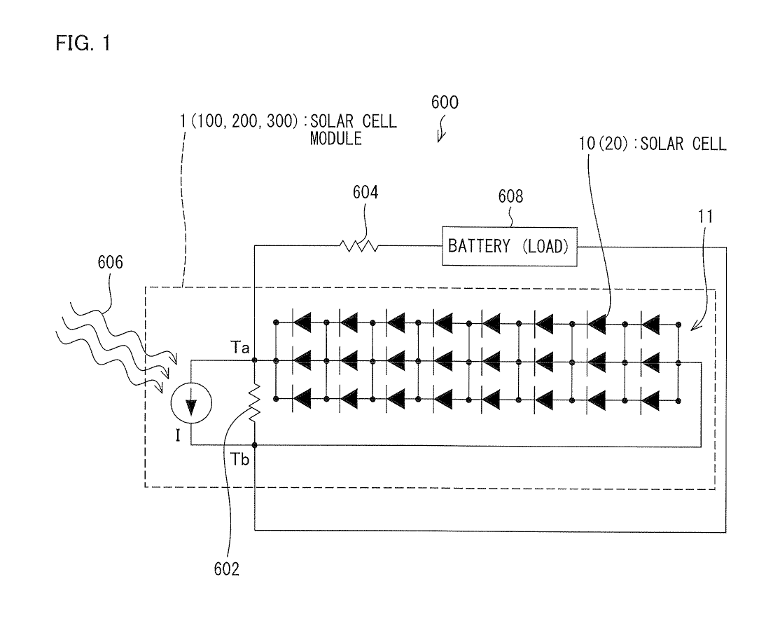

The following describes a solar cell module of the present invention. FIG. 1 is a circuit diagram illustrating one example of a circuit configuration of a solar battery which includes the solar cell module of the present invention.

In a solar battery 600 illustrated in FIG. 1, a solar cell module 1 of the present invention is connected in series with a series circuit made up of: a battery 608 which is a load; and an electric resistance 604.

As illustrated in FIG. 1, the solar cell module 1 includes a plurality of solar cells (e.g., 24 solar cells in FIG. 1) 10 which are two-dimensionally arranged. Each of the solar cells 10 includes a light-receiving surface for receiving light such as solar light. Although this is described later in detail, employed as the solar cells 10 may be (i) so-called back-side-electrode-type solar cells each of which has terminals (a positive electrode terminal and a negative electrode terminal) on its surface (lower surface) opposite to its light-receiving surface or (ii) so-called double-sided electrode type solar cells each of which has terminals (a positive electrode terminal and a negative electrode terminal) respectively on its light-receiving surface and its surface opposite thereto.

A solar cell 10 may be electrically connected with another solar cell 10 in any connection forms. In FIG. 1, every three solar cells 10 are connected in parallel to form eight parallel circuits which are connected in series. The eight parallel circuits which are connected in series are hereinafter referred to as a cell circuit section 11.

The solar cell module 1 is arranged such that a parallel circuit made up of: (i) a current source I which generates electromotive force and (ii) the cell circuit section 11 is provided across terminals Ta and Tb of the series circuit made up of the battery 608 and the electric resistance 604. In FIG. 1, a resistance 602 provided in parallel to the current source I and the cell circuit section 11 is a leak current equivalent resistance.

A light beam 606 is incident upon the light-receiving surface of a solar cell 10 of the solar cell module 1 of the solar battery 600 thus arranged, so that optical energy of the light beam 606 received by the solar cell 10 is converted into electrical energy by the solar cell 10. The electrical energy is supplied as a current from the solar cell 10 to the battery 608. Thus, electric power is supplied from the solar cell module 1 to the battery 608.

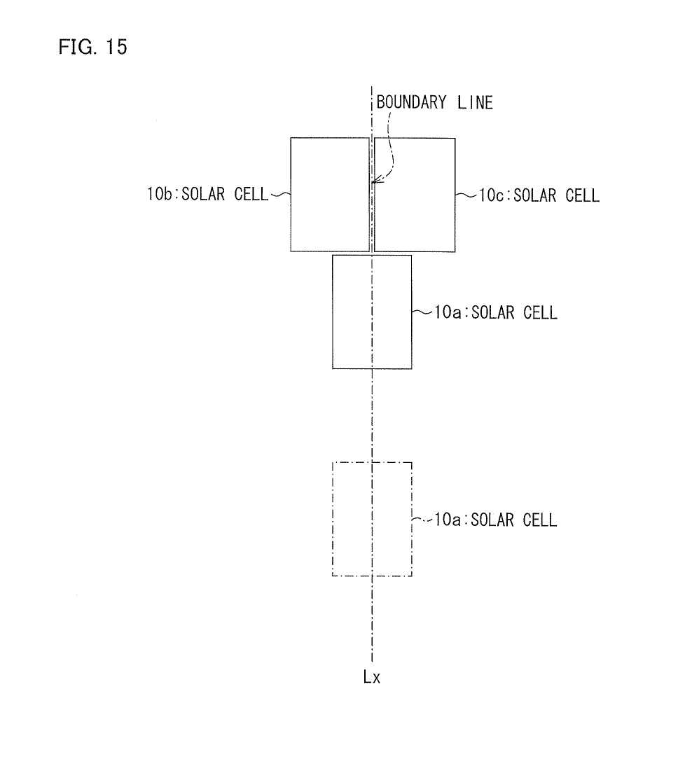

In the solar cell module 1 of the present invention which is provided to such a solar battery 600, the plurality of solar cells 10 are two-dimensionally arranged, and as illustrated in, e.g., FIG. 15, at least one of the plurality of solar cells 10 (hereinafter, referred to as solar cell 10a) is positioned on an extended line Lx which is extended from a boundary line between other adjacent solar cells 10 (referred to as solar cells 10b and 10c). FIG. 15 shows one example of how the solar cells 10 are positioned.

Thus, at least one of the plurality of solar cells 10 is positioned on the extension line Lx which is extended from a boundary line between other adjacent solar cells 10. This allows the solar cell module 1 to have a structure difficult to bend and twist even if bending stress and/or twisting stress is applied to the extension line Lx.

This makes it possible to avoid such a situation that as is the case with a conventional solar cell module in which solar cells are arranged so that a boundary line between any two adjacent solar cells is positioned on a single straight line, bending stress and/or twisting stress applied to the solar cell module 1 concentrates at such boundary lines.

As a result, as compared to the conventional solar cell module, the solar cell module 1 of the present invention has a higher stiffness against bending stress and/or twisting stress which may be applied thereto.

In FIG. 15, continuous lines are used to illustrate how the solar cell 10a is immediately adjacent to the solar cells 10b and 10c. However, the position of the solar cell 10a is not limited to this. That is, even if the solar cell 10a is spaced from the adjacent solar cells 10a and 10c, a certain effect can be obtained in terms of stiffness (strength) against bending stress and/or twisting stress, provided that, as indicated with e.g. a virtual line in FIG. 15, the solar cell 10a is positioned on the extension line Lx which is extended from the boundary line between the solar cells 10a and 10c.

A solar cell module 100 of the present invention may be concretely realized as the following embodiments. The following describes concrete embodiments of the solar cell module 1 of the present invention, with reference to drawings.

### Embodiment 1

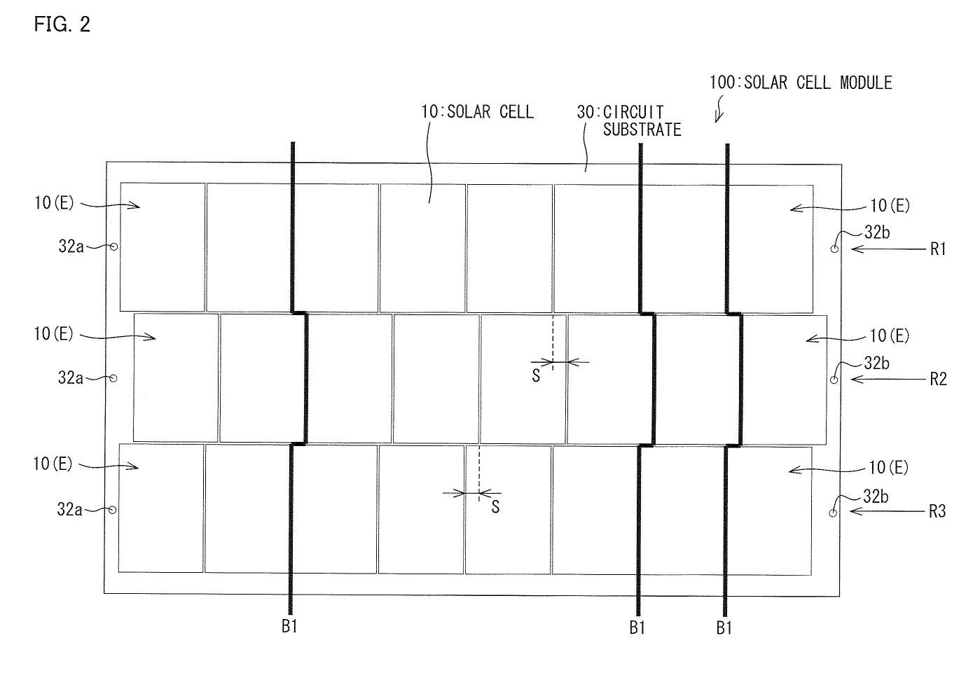

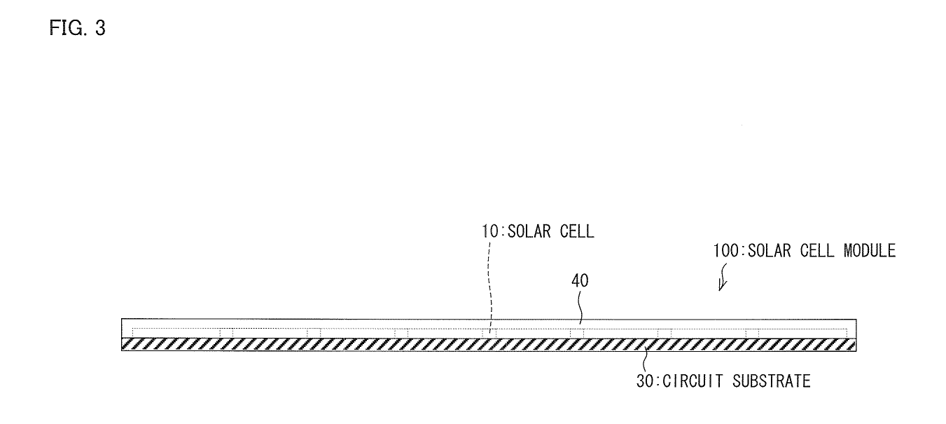

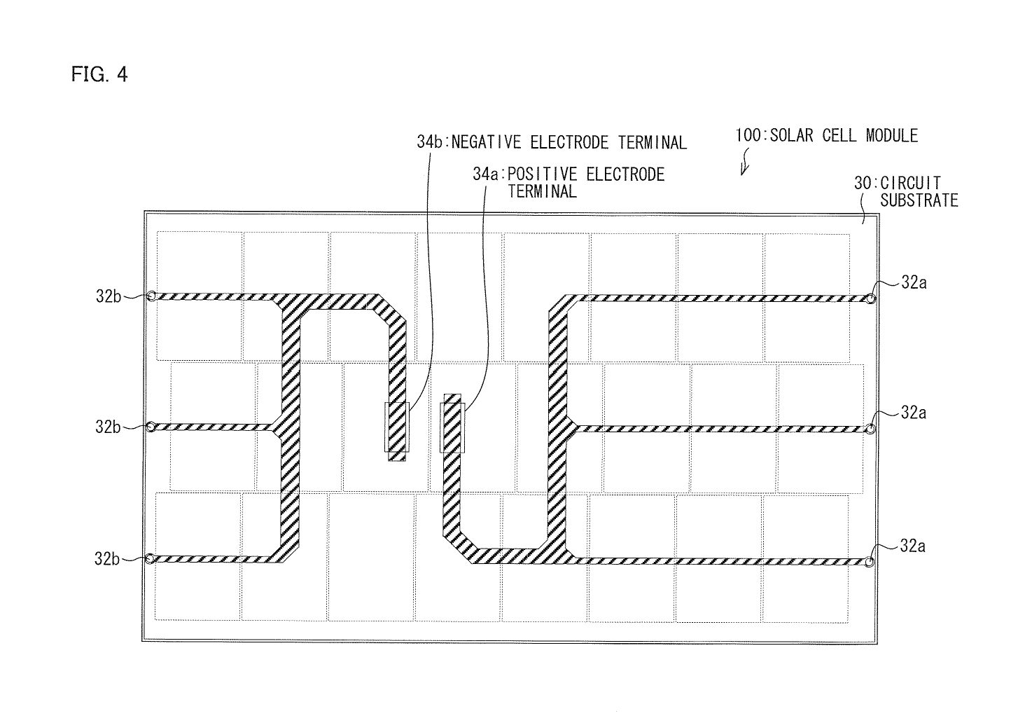

FIG. 2 is a plan view illustrating an appearance of Embodiment 1 (solar cell module 100) of the solar cell module 1 of the present invention. FIG. 3 is a side view of the solar cell module 100 of Embodiment 1. FIG. 4 is a bottom view of the solar cell module 100.

The solar cell module 100 has, e.g., a length of 60 mm, a width of 105 mm, and a thickness of 0.8 mm. Each of the solar cells 10 has a length of 18 mm, a width of 12 mm, and a thickness of 0.11 mm. The solar cell module 100 includes the plurality of solar cells 10 and a circuit substrate 30 on which the solar cells 10 are mounted.

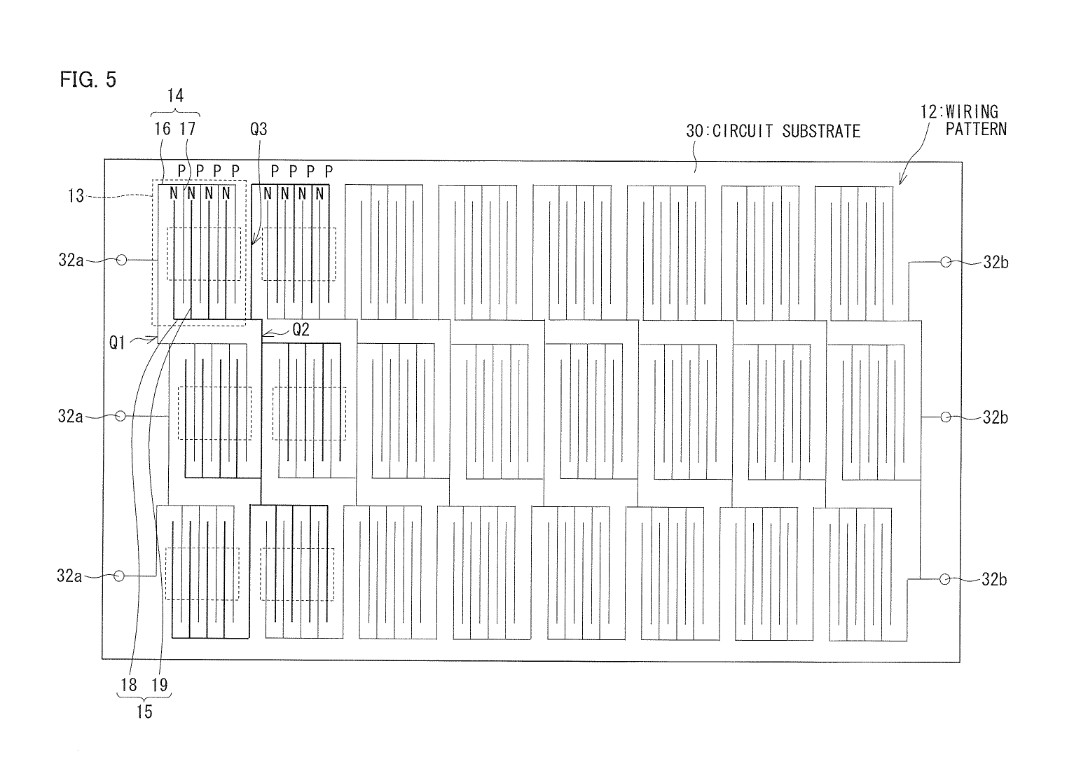

Provided on one surface of the circuit substrate 30 is a wiring pattern for electrically connecting the solar cells 10. FIG. 5 is a view illustrating one example of the wiring pattern on the circuit substrate 30.

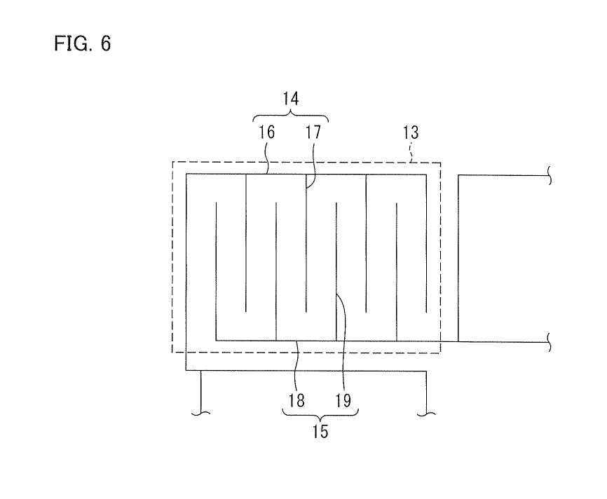

A wiring pattern 12 in FIG. 5 includes a plurality of comb-teeth wiring pattern sections 13. FIG. 6 is an enlarged view of one of the comb-teeth wiring pattern sections 13.

As illustrated in FIG. 6, the comb-teeth wiring pattern section 13 includes a first wiring pattern section 14 and a second wiring pattern section 15.

The first wiring pattern section 14 includes: a first wire 16 which is horizontally extended; and a plurality of second wires 17 which are extended downward from the first wire 16 at regular intervals. Each of the second wires 17 serves as a positive electrode to be connected with a positive electrode terminal 10P (to be described later; see FIG. 22) of the solar cell 10. The second wiring pattern section 15 includes: a third wire 18 which is horizontally extended; and a plurality of fourth wires 19 which are extended upward from the third wire 18 at regular intervals. Each of the fourth wires 19 serves as a negative electrode to be connected with a negative electrode terminal 10N (to be described later; see FIG. 22) of the solar cell 10.

The first wire 16 in the first wiring pattern section 14 and the third wire 18 in the second wiring pattern section 15 are extended in parallel to each other. The second wires 17 in the first wiring pattern section 14 and the fourth wires 19 in the second wiring pattern section 15 are extended in parallel to each other and alternately arranged in a horizontal direction.

The comb-teeth wiring pattern sections 13 thus arranged are provided so as to correspond to how the solar cells 10 are arranged on the circuit substrate 30. In FIG. 5 for example, three (60 mm/18 mm) solar cells 10 are arranged longitudinally (in an up-and-down direction; vertically), and eight (105 mm/12 mm) solar cells 10 are arranged laterally (in a right-and-left direction; horizontally). Accordingly, three comb-teeth wiring pattern sections 13 are arranged longitudinally (in the up-and-down direction; vertically), and eight comb-teeth wiring pattern sections 13 are arranged laterally (in the right-and-left direction; horizontally).

Each of the comb-teeth wiring pattern sections 13 is connected with another comb-teeth wiring pattern section 13 as below.

As illustrated in FIG. 5, any comb-teeth wiring pattern section 13 is connected with a longitudinally-adjacent comb-teeth wiring pattern section 13. Specifically, respective first wiring pattern sections 14 of two longitudinally-adjacent comb-teeth wiring pattern sections 13 are connected via a wire Q1, and respective second wiring pattern sections 15 are connected via a wire Q2.

Further, as illustrated in FIG. 5, any comb-teeth wiring pattern section 13 is also connected with a laterally-adjacent comb-teeth wiring pattern section 13. Specifically, the first wire 16 of one of two laterally-adjacent comb-teeth wiring pattern sections 13 and the third wire 18 of the other thereof are connected with each other.

The solar cells 10 are mounted on one surface (upper surface) of the circuit substrate 30 via a conductive joining material which is obtained by, e.g., curing a silver paste. Further, at least a transparent resin or a translucent resin is employed to encapsulate the upper surface of the circuit substrate 30, the upper surfaces (including the light-receiving surfaces) and the side surfaces of the solar cells 10 mounted on the circuit substrate 30. The encapsulation allows protection of the upper surface of the circuit substrate 30 and the upper and side surfaces of the solar cells 10.

In the present embodiment, each of the solar cells 10 has a rectangular surface which includes the light-receiving surface. In consideration of downsizing of the solar cell module 100, each of the solar cells 10 preferably has a shape of a flat plate.

As illustrated in FIG. 2, the plurality of solar cells 10 (e.g., 24 solar cells 10) are provided on the circuit substrate 30. In the solar cell module 100, solar cells 10 are arranged along a straight line parallel to one of two sides of the rectangular shape of a solar cell 10, and cell rows thus formed are arranged in a direction in which the other one of the two sides is extended. For example, as described above, the solar cells 10 are two-dimensionally arranged so as to form a two-dimensional array having 3 rows and 8 lines. Any two adjacent solar cells 10 have a space of, e.g., 0.3 mm therebetween.

The solar cells 10 which constitutes the solar cell module 100 of the present embodiment are back-side-electrode-type solar cells each of which has positive electrode terminals 10P (see FIG. 22) and negative electrode terminals 10N (see FIG. 22) on its surface (lower surface) opposite to its light-receiving surface.

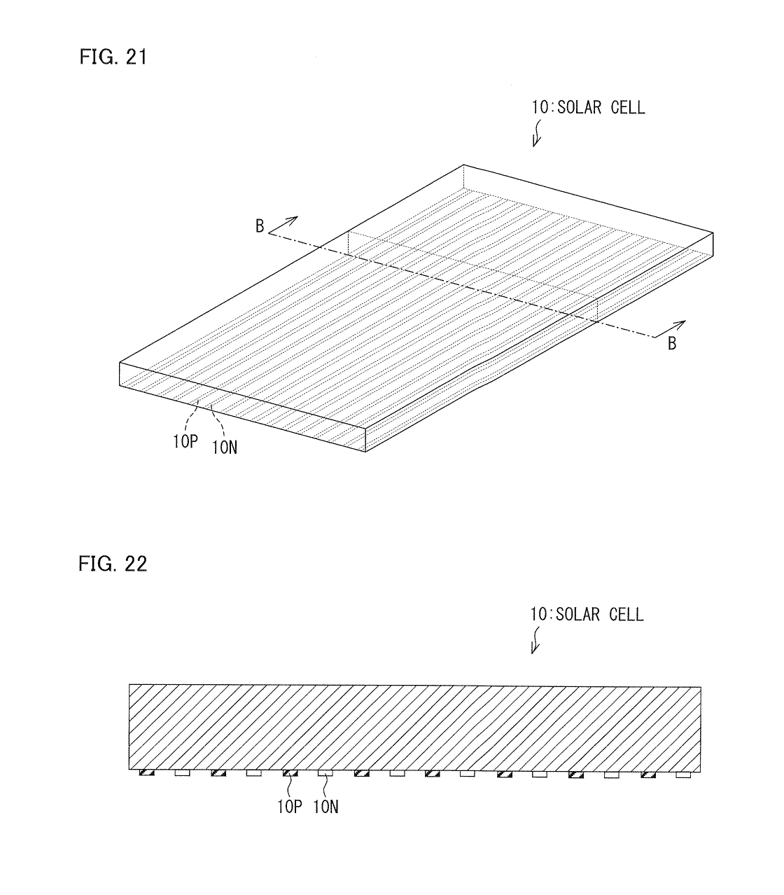

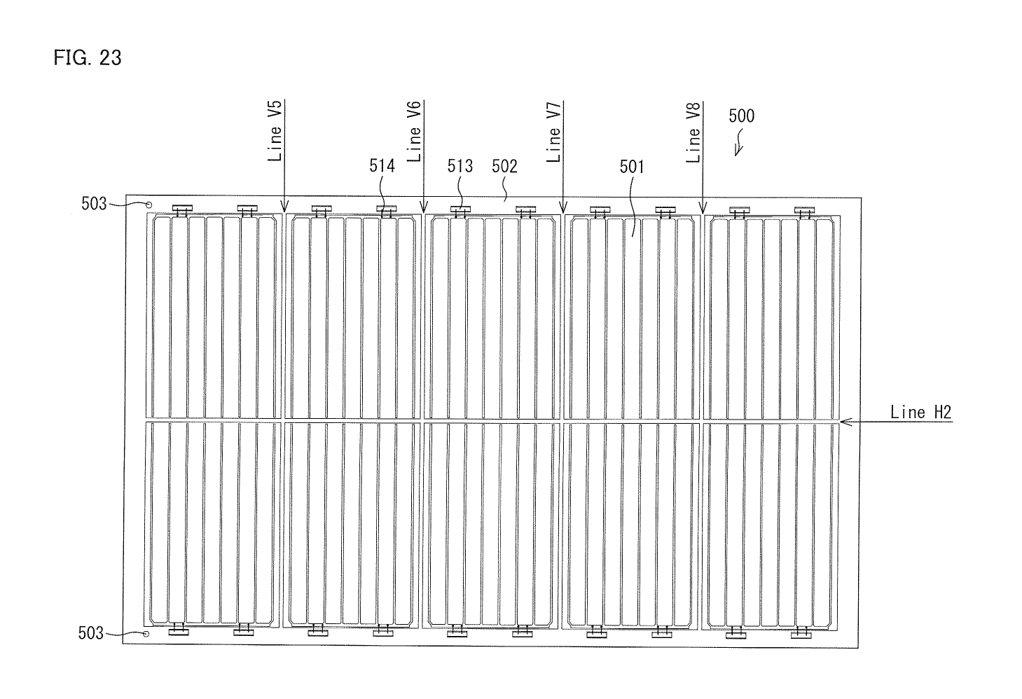

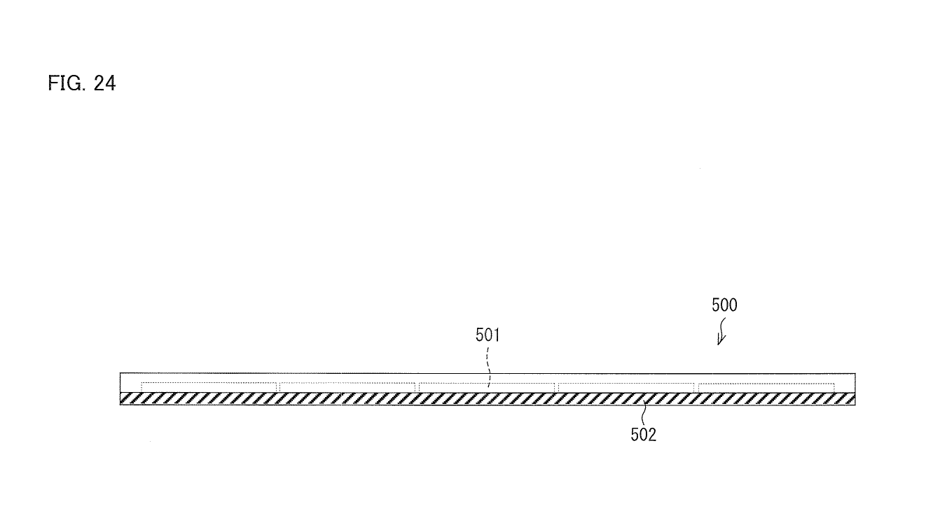

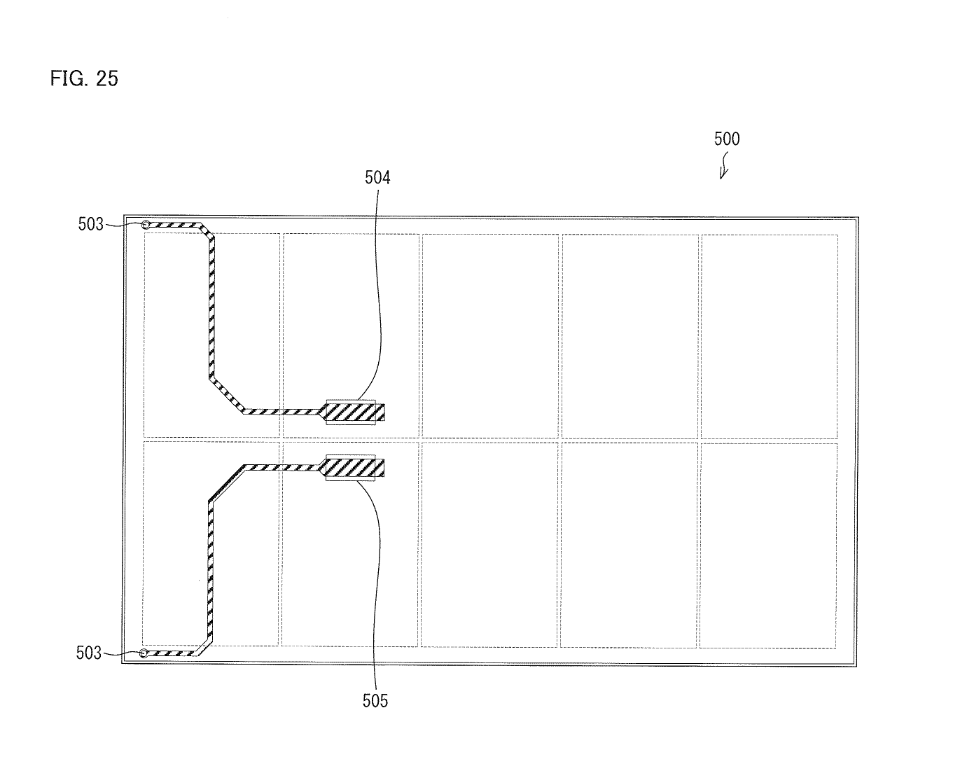

FIG. 21 is an external view illustrating one example of one of the back-side-electrode-type solar cells. FIG. 22 is a cross-sectional view illustrating a cross-section taken along a line B-B with arrows in FIG. 21.

As illustrated in FIGS. 21 and 22, the back-side-electrode-type solar cell 10 includes the positive electrode terminals 10P and the negative electrode terminals 10N on its surface opposite to the light-receiving surface, and are connected with the circuit substrate 30 via the positive and negative electrode terminals 10P and 10N, the wires of the circuit substrate 30, etc., in accordance with, e.g., a predetermined connection form. Further, the positive electrode terminals 10P and the negative electrode terminals 10N each have a zonal shape, and are alternately arranged at predetermined intervals.

As describe above, when the solar cells 10 are mounted on the circuit substrate 30, each of the positive electrode terminals 10P is connected with a second wire 17 which is provided on the circuit substrate 30 and serves as a positive electrode. Similarly, when the solar cells 10 are mounted on the circuit substrate 30, each of the negative electrode terminals 10N is connected with a fourth wire 19 which is provided on the circuit substrate 30 and serves as a negative electrode.

See FIG. 2 again. The circuit substrate 30 has through holes 32a and 32b in appropriate positions. Among the solar cells 10 in the cell circuit section 11 (see FIG. 1), hereinafter referred to as “end cell 10 (E)” are solar cells 10 which are directly connected with both terminals of the cell circuit section 11. Wires on the circuit substrate 30 which are connected with the terminals of left-side end cells 10(E) are led to the lower surface of the circuit substrate 30 via the through holes 32a. Similarly, wires on the circuit substrate 30 which are connected with the terminals of right-side end cells 10(E) are led to the lower surface of the circuit substrate 30 via the through holes 32b.

As illustrated in FIG. 4, the positive electrode terminal 34a and the negative electrode terminal 34b are provided on the lower surface of the circuit substrate 30. The wires led to the lower surface of the circuit substrate 30 via the through holes 32a are connected with the positive electrode terminal 34a. Similarly, the wires led to the lower surface of the circuit substrate 30 via the through holes 32b are connected with the negative electrode terminal 34b.

In the connection form illustrated in FIG. 4, the plurality of wires led to the lower surface of the circuit substrate 30 via the through holes 32a are joined together before reaching the positive electrode terminal 34a. The joined wire is connected with the positive electrode terminal 34a. The same holds for the wires led to the lower surface of the circuit substrate 30 via the through holes 32b.

In the solar cell module 100 of the present embodiment, the solar cells 10 which are laterally (horizontally; in the right-and-left direction) arranged in FIG. 1 are connected in series via positive electrode terminals 12a, negative electrode terminals 12b, and a wiring pattern 12. In addition, the series circuit formed by the serial connections are longitudinally (in the up-and-down direction) connected in parallel in FIG. 1.

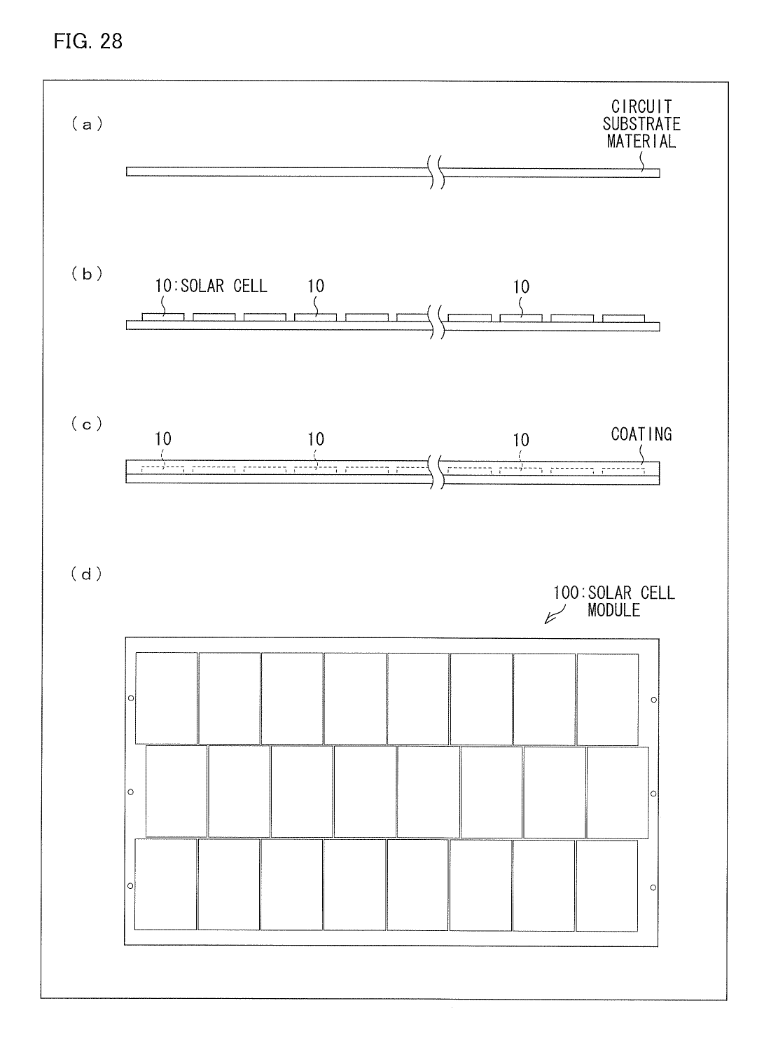

The following describes steps (method) of manufacturing the solar cell module 100. FIG. 28 is a view illustrating the manufacturing steps. Before starting the manufacturing, the circuit substrate 30 is a large rectangular plate material made up of connected circuit substrates. The plate material is referred to as circuit substrate material.

First, by use of a coating applicator, a conductive paste is applied to a predetermined position on the upper surface of the circuit substrate material illustrated in (a) of FIG. 28. Then, as illustrated in (b) of FIG. 28, the back-side-electrode-type solar cells 10 are arranged in predetermined positions on the circuit substrate material by a predetermined mounting apparatus so as to be temporarily fixed therein. Then, the conductive paste is cured by use of an oven.

Thus, the back-side-electrode-type solar cells 10 are completely fixed so as not to drop off from the circuit substrate material. At this point, the positive electrode terminals 10P (see FIG. 22) provided on the lower surface of the back-side-electrode-type solar cells 10 are connected with the second wires 17 in the wiring pattern 12, and the negative electrode terminals 10N (see FIG. 22) provided on the lower surface are connected with the fourth wires 19 in the wiring pattern 12.

Then, as illustrated in (c) of FIG. 28, at least the transparent resin or the translucent resin is applied onto the surface of the circuit substrate material on which the back-side-electrode-type solar cells 10 are mounted, so that the surfaces of the circuit substrate material and the back-side-electrode-type solar cells 10 are encapsulated (encapsulation step).

It follows that after the encapsulated circuit substrate material is cut in a subsequent cutting step, encapsulated in at least the transparent resin or the translucent resin are the upper surface of the circuit substrate 30 and the upper surfaces (including the light-receiving surfaces) and the side surfaces of the solar cells 10 mounted on the upper surface of the circuit substrate 30.

The encapsulation can be carried out in a step in which at least the transparent resin or the translucent resin is applied and cured (application/curing step). One example of this step is a mold encapsulation step utilizing a molding die and a transparent epoxy resin.

The encapsulation may also be carried out in a step in which a sheet material made of at least the transparent resin or the translucent resin is bonded by the application of heat and pressure (laminate encapsulation step; thermocompression bonding step). One example which can be employed as the sheet material is an olefinic sheet material or a sheet material made of an ethylene-vinyl acetate copolymer. Another sheet material made of polyethylene terephthalate may be provided thereon further.

Further, the encapsulation may also be carried out in a step in which the circuit substrate material and the solar cells 10 are coated with a liquid transparent resin by use of a dispenser.

Lastly, the encapsulated circuit substrate material is cut, by use of a predetermined cutting device, into pieces having a predetermined size. Thus, a plurality of solar cell modules 100 are completed as illustrated in (d) of FIG. 28.

In addition to the arrangement above, the solar cell module 100 of the present embodiment is arranged such that one of two cell rows which are longitudinally (in the up-and-down direction) adjacent is displaced, with respect to the other one of the two cell rows, in a direction along a longer side of the cell rows (the direction corresponds to a “direction in which the one side is extended” in claim 2 in the Claims).

For example, among three cell rows R1 through R3 which are adjacent in the up-and-down direction, solar cells 10 in the middle cell row R2 are horizontally (rightward in FIG. 1) displaced, by a predetermined distance S (e.g., S=2 mm), with respect to solar cells 10 in the upper cell row R1.

Similarly, the solar cells 10 in the middle cell row R2 are horizontally (rightward in FIG. 1) displaced, by the predetermined distance S (e.g., S=2 mm), with respect to solar cells 10 in the lower cell row R3. That is, each of the solar cells 10 which are two-dimensionally arranged is positioned on an extended line which is extended from a boundary line between adjacent solar cells 10 which are longitudinally adjacent to the former solar cell 10.

This state can be described such that, among boundary lines each formed between adjacent solar cells 10, vertical boundary lines B1 (in FIG. 2, part of the boundary lines are indicated with bold lines) have folding points between an upper end of the solar cell module 100 to the lower end thereof.

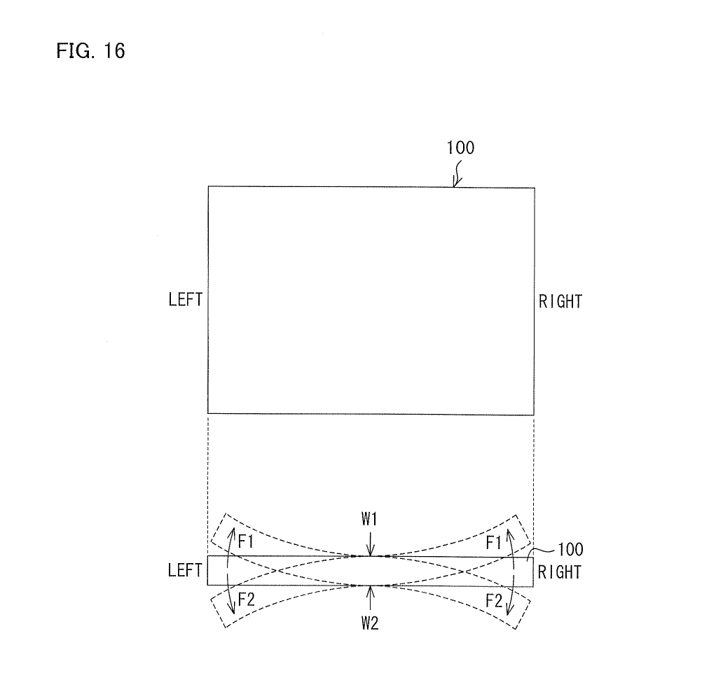

FIG. 16 shows: a schematic plan view illustrating the solar cell module 100 of FIG. 2; a bottom view illustrating the solar cell module 100 as viewed from below; and one example of how the solar cell module 100 is deformed in a case where horizontal stresses F1 and F2 are applied to the solar cell module 100.

As illustrated in FIG. 16, the horizontal bending stress F1 refers to a stress which causes bending of the solar cell module 100 so that a right region and a left region on one surface W1 of the solar cell module 100 come close to each other. Similarly, the horizontal bending stress F2 refers to a stress which causes bending of the solar cell module 100 so that a right region and a left region on the other surface W2 of the solar cell module 100 come close to each other.

A conventional solar cell module is arranged such that among boundary lines between adjacent solar cells, vertical boundary lines have no folding point between the upper end of the solar cell module to the lower end thereof. In this case, the solar cell module has a problem in that in a case where the horizontal bending stresses F1 and F2 are applied to the solar cell module, the bending stresses F1 and F2 concentrate at positions on the circuit substrate which positions correspond to the boundary lines having no folding point, so that the solar cell module is likely to be cracked in the positions.

In contract, thesolar cell module 100 of the present embodiment is arranged such that as described above, each of the vertical boundary lines B1 has folding points between the upper end to the lower end of the solar cell module 100 (each of the solar cells 10 which are two-dimensionally arranged is positioned on an extended line which is extended from a boundary line between adjacent solar cells 10 which are longitudinally adjacent to the former solar cell 10). This gives the solar cell module 100 a structure which is difficult to bend and twist even if bending stress and twisting stress are applied to the extended line of the boundary line.

Thus, the solar cell module 100 thus arranged can achieve its high stiffness (strength; toughness) against the horizontal bending stresses F1 and F2, as compared to the conventional solar cell module.

### Embodiment 2

A solar cell module of the present embodiment is different, in attitude of the solar cells 10, from the solar cell module 100 of Embodiment 1. Except for this, the solar cell module of the present embodiment is the same as the solar cell module 100 of Embodiment 1.

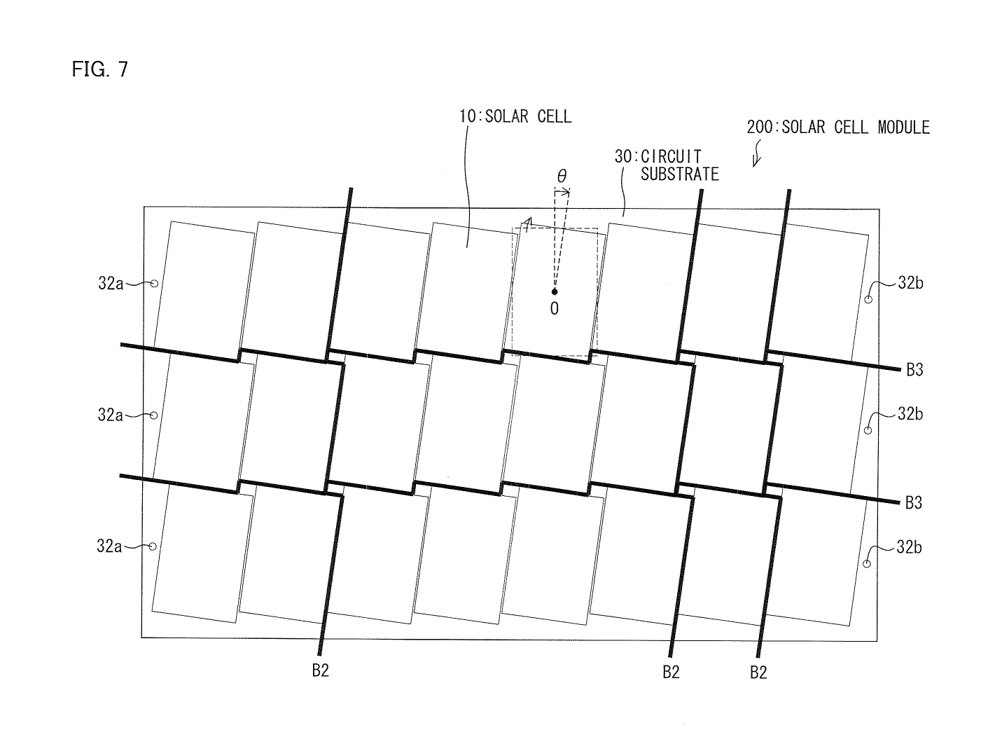

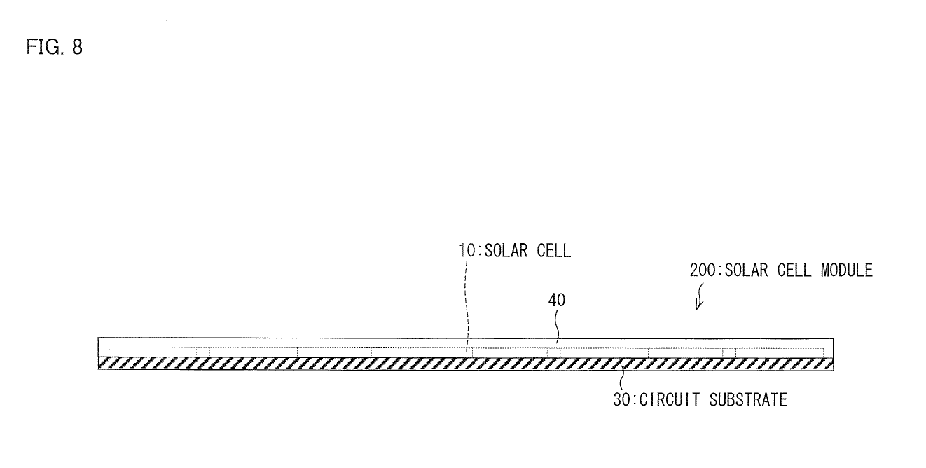

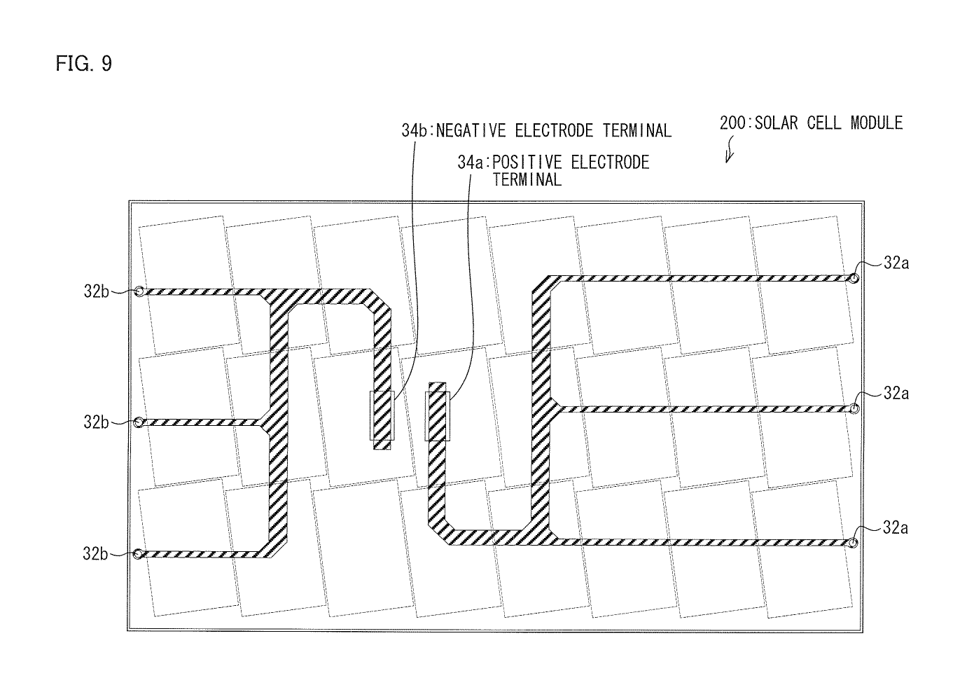

Therefore, the following deals with only differences between the solar cell module of the present embodiment and the solar cell module 100 of Embodiment 1. FIG. 7 is a plan view illustrating an appearance arrangement of Embodiment 2 (solar cell module 200) of the solar cell module of the present invention. FIG. 8 is a side view of the solar cell module 200 of Embodiment 2. FIG. 9 is a bottom view of the solar cell module 200. Members which are the same as those of the solar cell module 100 of Embodiment 1 are given common reference numerals.

As illustrated in FIGS. 7 through 9, the solar cell module 200 of the present embodiment is arranged such that each of the solar cells 10 is disposed so that one side of its rectangular shape is tilted by a predetermined angle with respect to a direction in which the solar cells 10 are arranged (first direction).

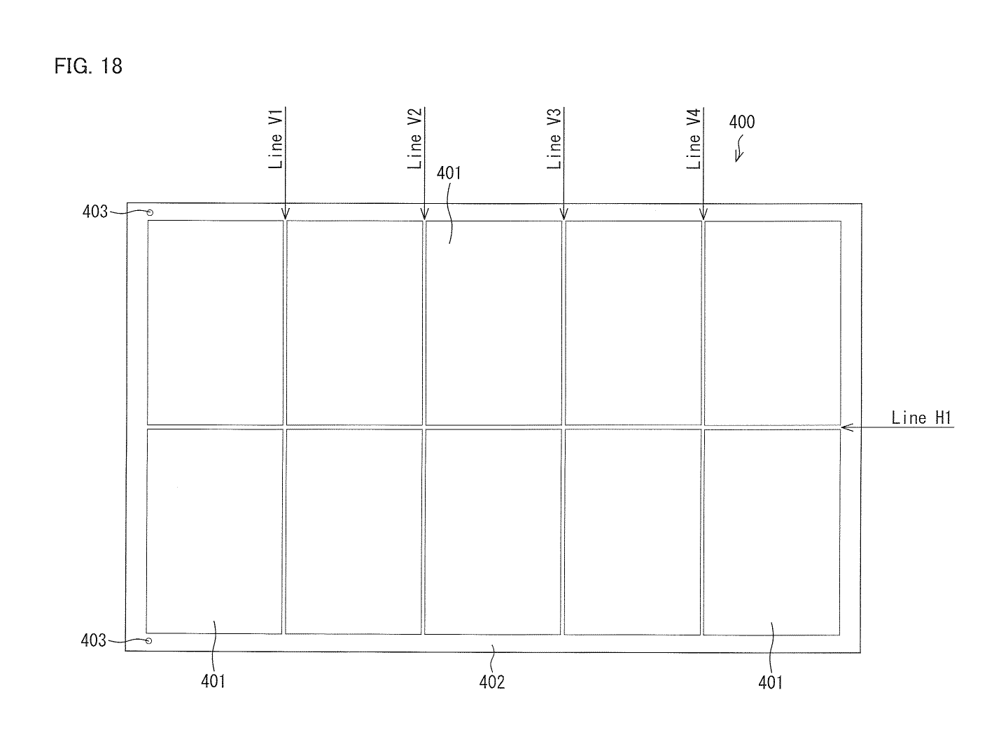

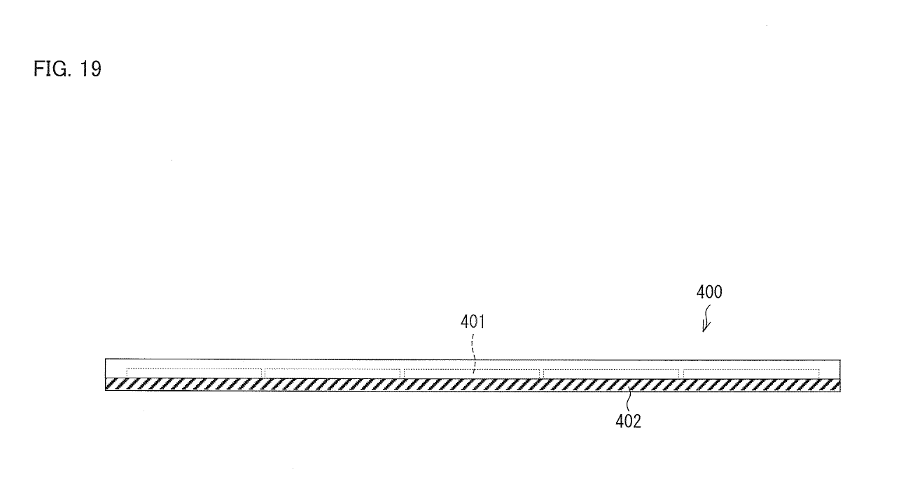

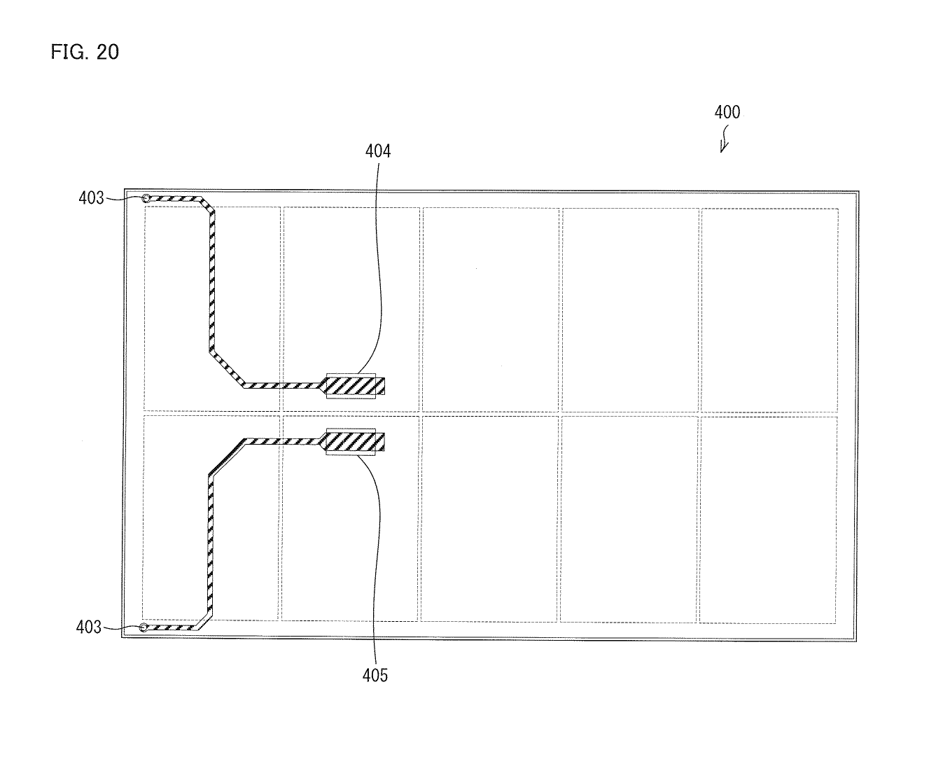

In other words, the solar cells 10 have an attitude (hereinafter, referred to as second attitude) obtained by rotating solar cells 10 around the centers O thereof in a predetermined direction by a predetermined angle with respect to their attitude (hereinafter, referred to as first attitude; e.g., an attitude of the solar cells of the conventional solar cell module illustrated in FIG. 18) in such a disposition that: centers of rectangular shapes of the solar cells 10 respectively match centers of rectangles in a grid formed by (i) a plurality of first lines which are extended in the first direction at regular intervals and (ii) a plurality of second lines which are extended in the second direction at regular intervals; and the sides of the rectangular shapes of the solar cells 10 are parallel to the sides of the rectangles in the grid.

In a case where the circuit substrate 30 has a rectangular shape, directions in which two adjacent sides thereof are extended correspond to the first and second directions, respectively.

In the solar cell module illustrated in FIG. 18 etc., the solar cells are mounted on the circuit substrate in such an attitude that the sides of rectangular shapes of the solar cells are parallel with the sides of the rectangular circuit substrate (i.e., in the first attitude).

In contrast, as illustrated in FIG. 7, the solar cells 10 in the solar cell module 200 of the present embodiment take the second attitude obtained by rotating (tilting) the solar cells 10 of the conventional solar cell module around the centers O thereof in a predetermined direction by a predetermined angle θ (in FIG. 7, θ is, e.g., 7.7° clockwise (approximately 0.13 rad)) with respect to the attitude of the solar cells 10 (first attitude). The predetermined angle θ is determined by parameters such as an aspect ratio of the solar cells 10, and an interval between adjacent solar cells 10. How an angle θ of 7.7° is found is described later.

According to the arrangement, each of the solar cells 10 has two kinds of boundary lines which are orthogonal to each other in two directions. In the case of Embodiment 1, solar cells 10 are positioned only on an extended line of boundary line extended in one direction. In the present embodiment, in contrast, solar cells 10 are positioned on the two kinds of boundary lines which are extended in the two directions.

This can also be described as below: in a case where boundary lines extended in one direction (in the vertical direction; the up-and-down direction) are connected to form a connected line B2, the connected line B2 has folding points between the upper end and the lower end of the solar cell module 200; and in a case where boundary lines extended in a direction orthogonal to the one direction (i.e., in the horizontal direction; the right-and-left direction) are connected to form a connected line B3, the connected line B3 has folding points between the right end and the left end of the solar cell module 200.

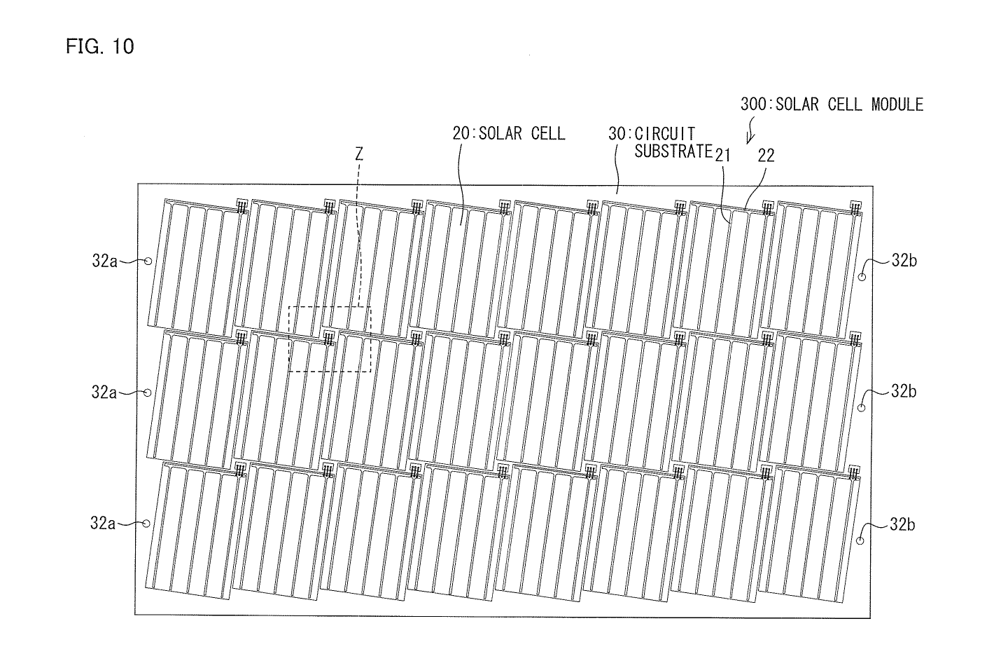

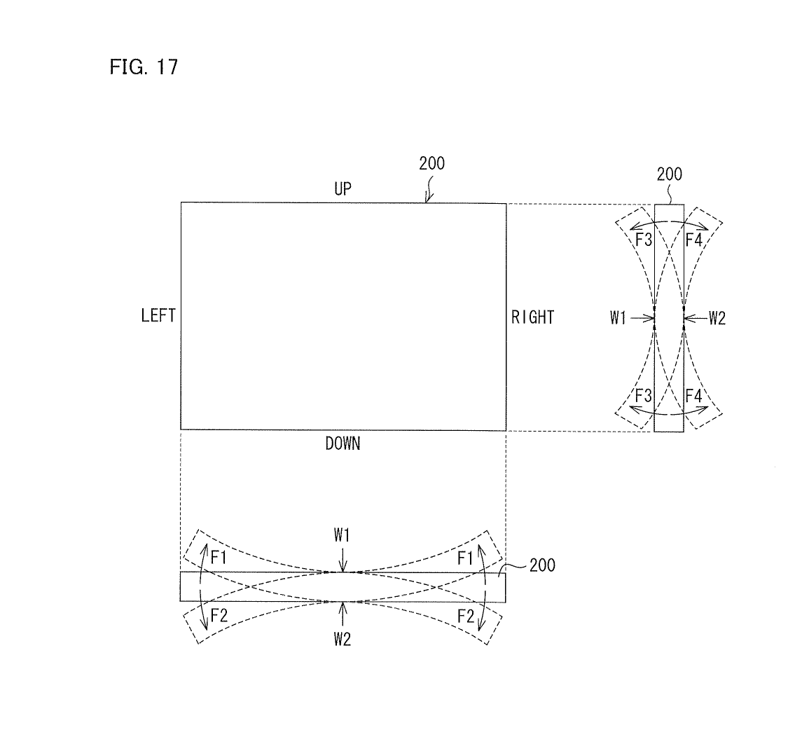

FIG. 17 shows: a schematic plan view illustrating the solar cell module 200 of FIG. 10; a bottom view illustrating the solar cell module 200 as viewed from below; a side view illustrating the solar cell module 200 from right; one example of how the solar cell module 200 is deformed in a case where horizontal stresses F1 and F2 are applied to the solar cell module 200; and one example of how the solar cell module 200 is deformed in a case where vertical stresses F3 and F4 are applied to the solar cell module 200.

As illustrated in FIG. 17, the horizontal bending stresses F1 and F2 are the same as those illustrated in FIG. 16.

The vertical bending stress F3 refers to a stress which causes bending of the solar cell module 200 so that an upper region and a lower region on one surface W1 of the solar cell module 200 come close to each other. Similarly, the vertical bending stress F4 refers to a stress which causes bending of the solar cell module 200 so that an upper region and a lower region on the other surface W2 of the solar cell module 200 come close to each other.

A conventional solar cell module (e.g., the solar cell module in FIG. 18) has boundary lines with no folding point not only along the vertical direction but also along the horizontal direction between the right end and the left end of the solar cell module. In this case, the solar cell module has a problem in that in a case where the vertical bending stresses F3 and F4 are applied to the solar cell module, the bending stresses F3 and F4 concentrate at positions on the circuit substrate which positions correspond to the boundary lines having no folding point, so that the solar cell module is likely to be cracked in the positions.

In contrast, the solar cell module 200 of the present embodiment is not only arranged such that as described above, the connected lines (boundary lines) B2 (see FIG. 2) which are vertically extended each have folding points between the upper end and the lower end of the solar cell module 200, but also arranged such that the connected lines (boundary lines) B3 (see FIG. 7) which are horizontally extended each have folding points between the right end and the left end of the solar cell module 200. Accordingly, the solar cell module 200 thus arranged can achieve its high stiffness (strength; toughness) not only against the horizontal bending stresses F1 and F2 but also against the vertical bending stresses F3 and F4, as compared to the conventional solar cell module.

Thus, the solar cell module 200 of the present embodiment has a high stiffness (strength) against twisting stress which is resultant force of the horizontal bending stresses and the vertical bending stresses.

### Embodiment 3

A solar cell module of the present embodiment is different from the solar cell module200 of Embodiment 2 in kinds of solar cells and in some points related thereto. Except for these, the solar cell module of the present embodiment is the same as the solar cell module 200 of Embodiment 2.

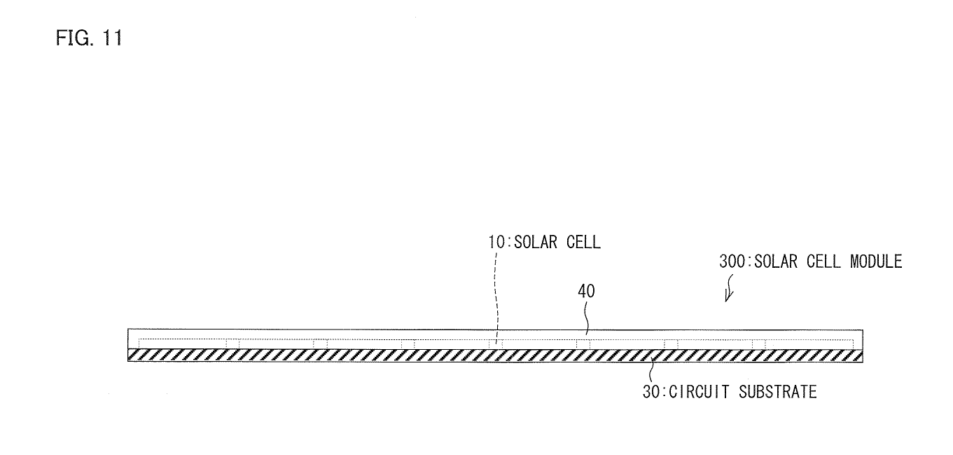

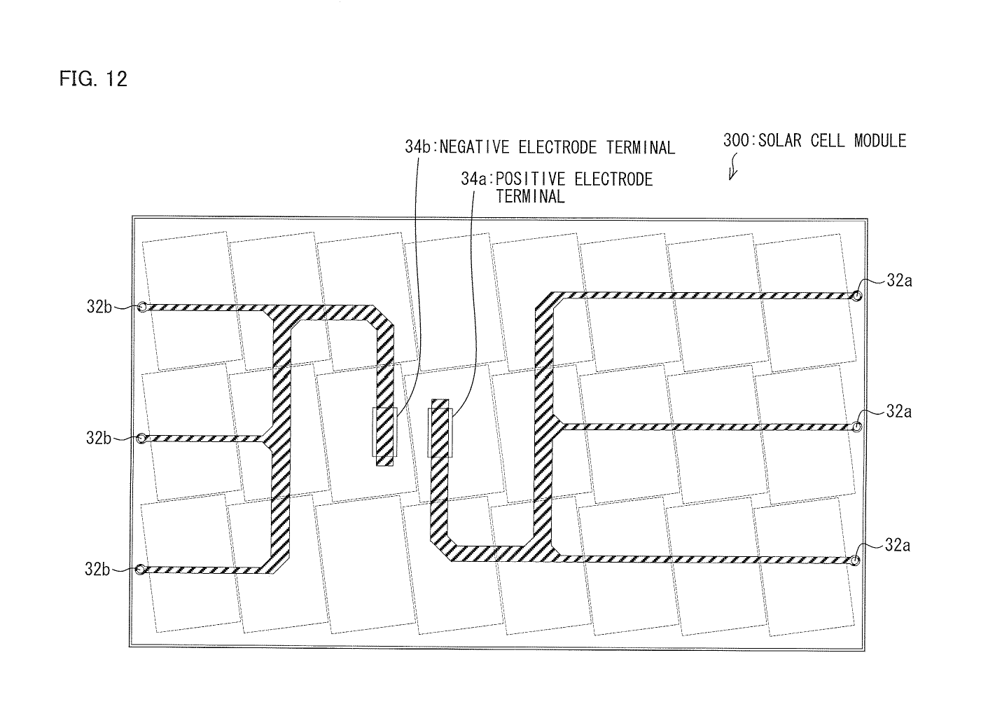

Therefore, the following deals with only differences between the solar cell module of the present embodiment and the solar cell module 200 of Embodiment 2. FIG. 10 is a plan view illustrating an appearance arrangement of Embodiment 3 (solar cell module 300) of the solar cell module of the present invention. FIG. 11 is a side view of the solar cell module 300 of Embodiment 3. FIG. 12 is a bottom view of the solar cell module 300. Members which are the same as those of the solar cell modules 100 and 200 of Embodiments 1 and 2 are given common reference numerals.

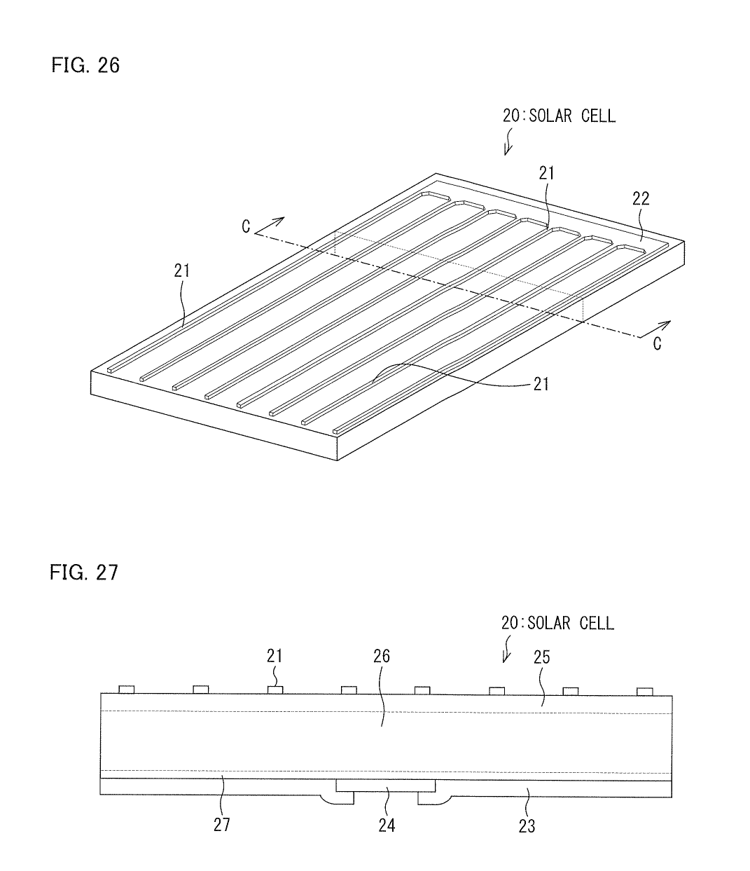

The solar cell module 300 of the present embodiment has, e.g., a length of 60 mm, a width of 105 mm, and a thickness of 0.8 mm. As illustrated in FIGS. 10 through 12, the solar cell module 300 of the present embodiment is arranged such that solar cells 20 are the double-sided electrode type solar cells. Accordingly, the solar cells 20 of the present embodiment may be, e.g., double-sided electrode type solar cells illustrated in FIGS. 26 and 27. FIG. 26 is an external view illustrating one example of one of the solar cells (double-sided electrode type solar cells) 20 of the present embodiment. FIG. 27 is a cross-sectional view illustrating a cross-section taken along a line C-C with arrows in FIG. 26.

The double-sided electrode type solar cell 20 illustrated in FIGS. 26 and 27 has negative electrode terminals on its surface with a light-receiving surface, and has positive electrode terminals on its opposite surface.

The double-sided electrode type solar cell 20 has, on its upper surface, collector sections 91 and a binding section which binds the collector sections 21.

The collector sections 21 have an elongated shape extended in one direction along the light-receiving surface, and are arranged in a direction orthogonal to the one direction at regular intervals. The binding section 22 has a shape extended in the direction orthogonal to the direction in which the collector sections 21 are extended (i.e., in the one direction), and is connected with ends of the collector sections 21.

Provided on the lower surface of the double-sided electrode type solar cell 20 are an aluminum layer 23 formed by sintering aluminum and a silver layer 24 formed by sintering silver. The silver layer 24 is provided at the center of the lower surface, and the aluminum layer 23 is provided so as to enclose the silver layer 24. A part of the aluminum layer 23 is provided so as to cover a part of the silver layer 24.

The double-sided electrode type solar cell 20 has a semiconductor substrate. As illustrated in FIG. 27, the semiconductor substrate is, e.g., a p-n junction diode made up of an N+ layer 25, a P− layer 26, and a P+ layer 27 which are provided from the upper surface to the lower surface. A surface (exposed surface) of the N+ layer 25 serves as the light-receiving surface.

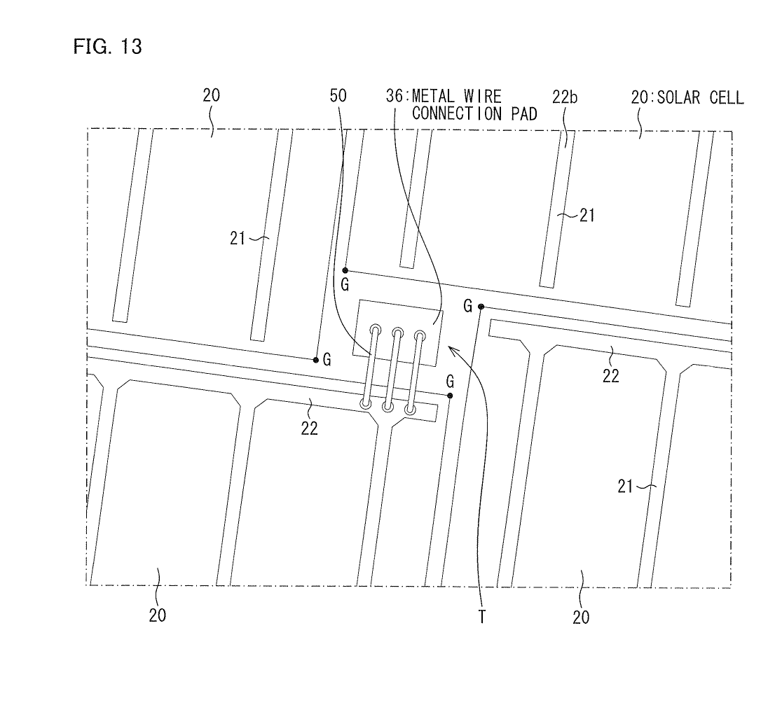

In the solar cell module 30 of the present embodiment, the solar cells 20 are tilted (rotated) as is the case with the solar cell module 200 of Embodiment 2. Accordingly, any four adjacent solar cells 20 have respective four vertexes which face each other, and a space is defined in the vicinity of the four vertexes. FIG. 13 is an enlarged view illustrating the vicinity of those vertexes G of four adjacent solar cells 20 which face each other which vicinity corresponds to an region enclosed by a dashed line indicated with “Z” in FIG. 10.

In the solar cell module 300 of the present embodiment, a metal wire connection pad 36 is provided in a space T. The metal wire connection pad 36 is connected with terminals (in the present embodiment, the positive electrode terminals) of a solar cell 20. The metal wire connection pad 36 and the positive electrode terminals of the solar cell 20 can be electrically connected via metal wires 50 such as gold wires.

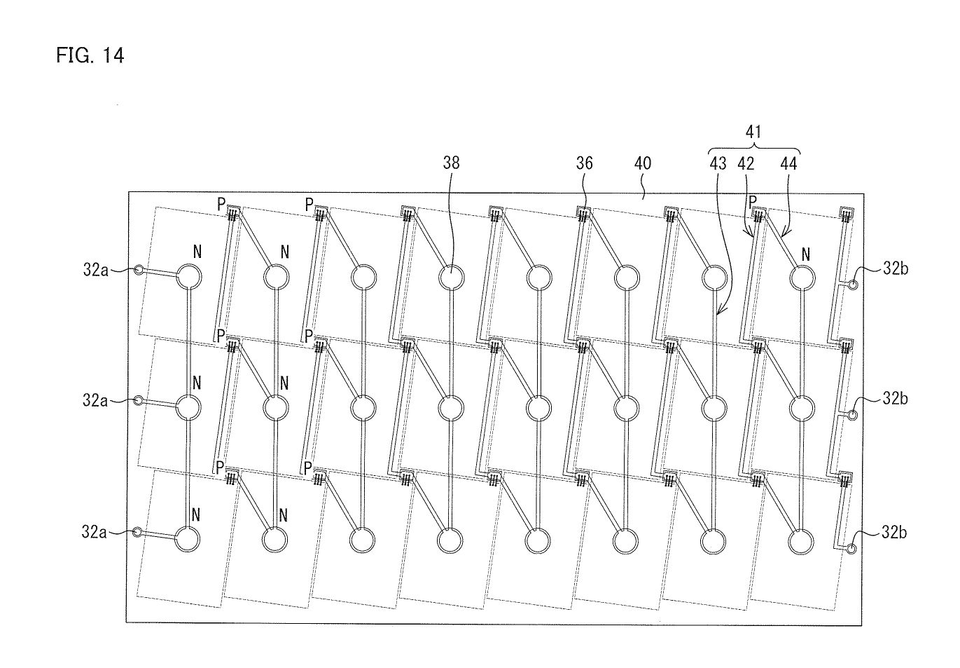

Wiring patterns 41 are provided on one surface (surface on which the solar cells 20 are mounted) of the circuit substrate 30 of the solar cell module 300. FIG. 14 is a view illustrating one example of the wiring patterns 41 on the circuit substrate 30.

Each of the wiring patterns 41 illustrated in FIG. 14 includes a first wire 42, a second wire 43, and a third wire 44.

The first wire 42 is a wire for connecting two vertically-adjacent metal wire connection pads 36 (P electrodes; positive electrodes). The second wire 43 is a wire for connecting two vertically-adjacent negative electrodes (N electrodes) 38. The third wire 44 is a wire for connecting a metal wire connection pad 36 with a negative electrode (N electrode) of a solar cell 20. The negative electrode (N electrode) 38 which is connected with the metal wire connection pad 36 via the third wire 44 is a negative electrode (N electrode) of a solar cell 20 which is horizontally adjacent to a solar cell 20 having a binding section 22 connected with the metal wire connection pad 36. In addition to the arrangement, as is the case with the solar cell module 200 of Embodiment 2, the solar cell module 300 of the present embodiment is also arranged such that the solar cells 20 take the second attitude which is obtained by rotating (tilting) the solar cells 20 around the centers O thereof in the predetermined direction by the predetermined angle θ (e.g., 7.7°) with respect to the first attitude.

The predetermined angle θ=7.7° is found by, e.g., the following calculation.

Assume that as described above, each of the solar cells has a length of 18 mm, a width of 12 mm, and a thickness of 0.11 mm, and any adjacent solar cells 20 have an interval of 0.3 mm therebetween.

Further, the number of collector sections 21 provided in one solar cell 20 is assumed to be 5. A sum of the width of each of the solar cells 20 (12 mm in this case) and the interval of adjacent solar cells 21 (0.3 mm in this case) is divided by the number of collector sections 21 provided in one solar cell 20 (5 in this case). In this case, an arrangement pitch D of the collector sections 21 is found by the following calculation: (12+0.3)/5=2.46 mm.

By providing the collector sections 21 at the arrangement pitch D, an arrangement pitch also takes 2.46 mm between (i) a collector section 21 of one of two horizontally-adjacent solar cells 20 which collector section is closest to the other one of the two horizontally-adjacent solar cells 20 and (ii) a collector section 21 of the other one of two horizontally-adjacent solar cells 20 which collector section 21 is closest to the one of the two horizontally-adjacent solar cells 20. That is, all the collector sections 21 on the solar cell module 300 are arranged at the identical arrangement pitch.

Further, the rotational angle θ is found so that the collector sections 21 of an upper one of two vertically-adjacent solar cells 20 and the collector sections 21 of a lower one of the two vertically-adjacent solar cells 20 are displaced by a distance corresponding to one collector section 21. (The rotational angle θ is found so that a collector section 21 located at, e.g., an end of the upper solar cell 20 and a collector section 21 located at the end of the lower solar cell 20 are arranged in the up-and-down direction, and upper ends (or lower ends) of the collector sections 21 are located on a straight line extended in the up-and-down direction.)

In this case, the rotational angle θ is expressed as:

θ=tan⁻¹ {D/(W+Y)}

where: a width of the solar cell 20 is W, the arrangement pitch is D, and the interval of the solar cells 20 is Y. In a case where the variables are substituted with the size of the solar cells 20 etc., the rotational angle θ is expressed as:

θ=tan⁻¹ {2.46/(18+0.3)}≈7.7°.

Thus, as is the case with the solar cell module 200 of Embodiment 2, the solar cell module 300 of the present embodiment can also achieve its high stiffness (strength; toughness) against the horizontal bending stresses F1 and F2 and against the vertical bending stresses F3 and F4, as compared to the conventional solar cell module.

Therefore, the solar cell module 300 of the present embodiment has a high stiffness (strength) against twisting stress which is resultant force of the horizontal bending stresses and the vertical bending stresses.

Further, the solar cell module 300 of the present embodiment makes it possible to produce the following effect for the reason that the metal wire connection pads 36 are provided in the spaces T which are brought about by disposing the solar cells 20 in the second attitude.

That is, in a case where the double-sided electrode type solar cells are employed as solar cells to be mounted on a solar cell module, in general, it is necessary to provide metal wire connection pads on the circuit substrate, and connect the metal wire connection pads with terminals (in the present embodiment, the negative electrode terminals) provided on upper surfaces of the double-sided electrode type solar cells.

In a matrix arrangement such as conventional solar cell modules, there are solar cells each of which is completely surrounded by other solar cells. In this case, it is conceivable that areas where the metal wire connection pads for such surrounded solar cells are provided are each assigned to a gap between respective parallelly-opposed sides of two adjacent solar cells (hereinafter, this is referred to as arrangement A).

In this case, the solar cells occupy a larger area. That is, it is necessary to employ metal wires to connect the metal wire connection pads with the terminals on the upper surfaces of the double-sided electrode type solar cells. In this case, used is a wire supply apparatus which is referred to as capillary. In use of the wire supply apparatus, a certain space (traffic line securing gap) is required for securing a traffic line along which the wire supply apparatus moves.

Due to the traffic line securing gap, an area occupied by the solar cells is increased. As a result, the solar cell module has an increased area.

In contrast, the solar cells 20 in the solar cell module 300 of the present embodiment take the second attitude. Although this somewhat causes increase in an area occupied by the solar cells 20, still, the effective utilization of the spaces T as spaces where the metal wire connection pads are provided makes it possible to achieve a smaller area which is occupied by the solar cells 20, while securing the traffic line of the wire supply apparatus, as compared to the arrangement A. This makes it possible to decrease a size of a solar cell module, as compared to the solar cell module of the arrangement A.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

For example, the plurality of solar cells to be mounted on one circuit substrate may have different sizes.

Further, by appropriately determining a wiring configuration of a wiring pattern (e.g., the wiring pattern 12 in FIG. 5) to be formed on the circuit substrate 30, it is possible to freely set the number and the connection form of the solar cells, a size of the light-receiving surface, or outputs (an output current and an output voltage) of the solar cell module.

Further, the shape of the circuit substrate is not limited to a rectangular shape. Further, the shape of the solar cells is not limited to a rectangular shape but may be any shape such as a circular shape, an elliptical shape, and a polygonal shape other than rectangular shapes. Further, two adjacent solar cells do not have to be identical in their shapes and in their sizes.

The present invention can also be described as below.

That is, a solar cell module of the present invention is a solar cell module including: a plurality of solar cells; and a circuit substrate, the plurality of solar cells being mounted on the circuit substrate in a plurality of rows, any adjacent ones of the plurality of rows being displaced from each other so that a boundary line between any adjacent solar cells in one row and a boundary line between any adjacent solar cells in a row adjacent to the one row do not form a straight line.

The solar cell module may be arranged such that: each of the plurality of solar cells has a rectangular shape; the plurality of solar cells are arranged such that solar cells are arranged on a straight line parallel to one of two adjacent sides of the rectangular shape, and a plurality of cell rows thus formed are arranged in a direction parallel to the other one of the two adjacent sides; and one of two adjacent ones of the cell rows is displaced, in a direction parallel to the one of two adjacent sides, with respect to the other one of the two adjacent ones of the cell rows.

According to the arrangement, the one of the two adjacent cell rows is displaced from the other one of the two adjacent cell rows in the direction in which the one side is extended. Accordingly, a solar cell in one cell row is positioned on an extended line of a boundary line between adjacent solar cells in an adjacent cell row. This makes it possible to achieve a structure which is difficult to bend and twist even if a bending stress and a twisting stress are applied to the boundary line.

This makes it possible to prevent from the solar cell module being bent and cracked at the boundary line, as compared to an arrangement in which a boundary line between two adjacent solar cells in one cell row and a boundary line between two adjacent solar cells in a cell row adjacent to the one cell row form a straight line.

The solar cell module is arranged such that: each of the plurality of solar cells has a rectangular shape; and each of the plurality of solar cells is disposed so that one side of its rectangular shape is tilted at a predetermined angle with respect to a direction in which the plurality of solar cells are arranged.

According to the arrangement, each of the plurality of solar cells is disposed so that one side of its rectangular shape is tilted at a predetermined angle with respect to a direction in which the plurality of solar cells are arranged. This results in such a structure that one solar cell is positioned on an extended line of a boundary line between solar cells adjacent to the one solar cell. That is, the structure is such that a cell in one cell row is positioned on an extended line of a boundary line between adjacent solar cells in an adjacent cell row. As a result, the structure is less affected by a bending stress and a twisting stress which are applied to the boundary line.

This makes it possible to prevent the solar cell module of the present invention from being bent and cracked in crossing two directions.

The solar cell module may further include: a circuit substrate on which the plurality of solar cells are mounted; and metal wire connection pads each of which is provided in a space which is formed in the vicinity of vertexes of rectangular shapes of four adjacent solar cells, the vertexes facing each other, the plurality of solar cells being double-sided electrode type solar cells each of which has, on its light-receiving surface, a terminal for one polarity, and has, on a surface opposite to the light-receiving surface, a terminal for the other polarity, the metal wire connection pads each of which is connected with the terminal for the one polarity.

According to the arrangement, a space is formed in the vicinity of vertexes of rectangular shapes of four adjacent solar cells which vertexes face each other, in a case where: double-sided electrode type solar cells are employed as the solar cells; each of the solar cells has a rectangular shape; and each of the solar cells is disposed so that one side of its rectangular shape is tilted at a predetermined angle with respect to a direction in which the solar cells are arranged.

According to the arrangement, the space is effectively utilized as a space where a metal wire connection pad is provided which is connected with a negative electrode terminal of a solar cell. This eliminates the need for separately providing the space where the metal wire connection pad is provided, or a space for securing a traffic line of a wire supply apparatus which is used in a case where the metal wire connection pad is connected with the terminal of the solar cell via a wire. This makes it possible to avoid or suppress increase in size of the circuit substrate, and consequently, increase in size of the solar cell module.

The solar cells may be back-side-electrode-type solar cells each of which has, on its surface opposite to its light-receiving surface, terminals for different polarities, or may be double-sided electrode type solar cells each of which has, on its light-receiving surface, a terminal for one polarity, and has, on its surface opposite to the light-receiving surface, a terminal for the other polarity.

Further, the solar cell module of the present invention further includes: a circuit substrate on which the plurality of solar cells are mounted, a surface of the circuit substrate and light-receiving surfaces of the plurality of solar cells mounted on the surface of the circuit substrate being encapsulated by at least a transparent resin or a translucent resin.

According to the arrangement, the encapsulation makes it possible to protect the solar cells and the circuit substrate.

A method for manufacturing any one of the solar cell modules, includes: the step of encapsulating, with at least a transparent resin or a translucent resin, (i) a surface of a circuit substrate on which the plurality of solar cells are mounted, and (ii) light-receiving surfaces of the plurality of solar cells mounted on the surface of the circuit substrate, the encapsulating being any one of (I) applying and curing at least the transparent resin or the translucent resin and (II) bonding, by application of heat and pressure, a sheet material made of at least the transparent resin or the translucent resin.

A solar cell module of the present invention may be a solar cell module in which at least four solar cells are mounted on a circuit substrate in rows, one of the rows being displaced from the other one of the rows so that boundary lines formed by the at least four solar cells do not form a cross-shape.

### INDUSTRIAL APPLICABILITY

The present invention is widely applicable to electronic devices including mobile information devices. Some examples of the mobile information device are portable electronic devices such as portable phones, GPS (Global Positioning System) receivers, desktop electronic dictionaries, digital still cameras, and video camcorders. The present invention is also applicable to remote controls of TVs or the like.

### REFERENCE SIGNS LIST

1, 100, 200, 300 Solar cell module
10 Solar cell, back-side-electrode-type solar cell
10a, 10b, 10c Solar cell
12 Wiring pattern
12a, 34a, 10P Positive electrode terminal
12b, 34b, 10N Negative electrode terminal
20 Solar cell, double-sided electrode type solar cell
30 Circuit substrate
36 Metal wire connection pad 38 (negative electrode)
50 Metal wire
B2 Metal wire (boundary line)
B3 Connected line (boundary line)
Lx Extended line
O Center
R1 through R3 Cell row
T Space
θ Predetermined angle

1. A solar cell module comprising a plurality of solar cells, the plurality of solar cells being two-dimensionally arranged, at least one of the plurality of solar cells being positioned on an extended line of a boundary line between solar cells adjacent to the at least one of the plurality of solar cells.

2. The solar cell module as set forth in claim 1,
wherein:
each of the plurality of solar cells has a rectangular shape;
the plurality of solar cells are arranged such that solar cells are arranged on a straight line parallel to one of two adjacent sides of the rectangular shape, and a plurality of cell rows thus formed are arranged in a direction parallel to the other one of the two adjacent sides; and
one of two adjacent ones of the cell rows is displaced, in a direction parallel to the one of two adjacent sides, with respect to the other one of the two adjacent ones of the cell rows.

3. The solar cell module as set forth in claim 1,
wherein:
each of the plurality of solar cells has a rectangular shape; and each of the plurality of solar cells is disposed so that one side of its rectangular shape is tilted at a predetermined angle with respect to a direction in which the plurality of solar cells are arranged.

4. The solar cell module as set forth in claim 3, further comprising: a circuit substrate on which the plurality of solar cells are mounted; and
metal wire connection pads each of which is provided in a space which is formed in the vicinity of vertexes of rectangular shapes of four adjacent solar cells, the vertexes facing each other,
the plurality of solar cells being double-sided electrode type solar cells each of which has, on its light-receiving surface, a terminal for one polarity, and has, on a surface opposite to the light-receiving surface, a terminal for the other polarity,
the metal wire connection pads each of which is connected with the terminal for the one polarity.

5. The solar cell module as set forth in claim 1,
wherein:
the plurality of solar cells are back-side-electrode-type solar cells each of which has, on its surface opposite to its light-receiving surface, terminals for different polarities.

6. The solar cell module as set forth in claim 2,
wherein:
the plurality of solar cells are back-side-electrode-type solar cells each of which has, on its surface opposite to its light-receiving surface, terminals for different polarities.

7. The solar cell module as set forth in claim 3,
wherein:
the plurality of solar cells are back-side-electrode-type solar cells each of which has, on its surface opposite to its light-receiving surface, terminals for different polarities.

8. The solar cell module as set forth in claim 1,
wherein:
the plurality of solar cells are double-sided electrode type solar cells each of which has, on its light-receiving surface, a terminal for one polarity, and has, on its surface opposite to the light-receiving surface, a terminal for the other polarity.

9. The solar cell module as set forth in claim 2,
wherein:
the plurality of solar cells are double-sided electrode type solar cells each of which has, on its light-receiving surface, a terminal for one polarity, and has, on its surface opposite to the light-receiving surface, a terminal for the other polarity.

10. The solar cell module as set forth in claim 3,
wherein:
the plurality of solar cells are double-sided electrode type solar cells each of which has, on its light-receiving surface, a terminal for one polarity, and has, on its surface opposite to the light-receiving surface, a terminal for the other polarity.

11. The solar cell module as set forth in claim 1, further comprising:
a circuit substrate on which the plurality of solar cells are mounted,
a surface of the circuit substrate and light-receiving surfaces of the plurality of solar cells mounted on the surface of the circuit substrate being encapsulated by at least a transparent resin or a translucent resin.

12. The solar cell module as set forth in claim 2, further comprising:
a circuit substrate on which the plurality of solar cells are mounted,
a surface of the circuit substrate and light-receiving surfaces of the plurality of solar cells mounted on the surface of the circuit substrate being encapsulated by at least a transparent resin or a translucent resin.

13. The solar cell module as set forth in claim 3, further comprising:
a circuit substrate on which the plurality of solar cells are mounted,
a surface of the circuit substrate and light-receiving surfaces of the plurality of solar cells mounted on the surface of the circuit substrate being encapsulated by at least a transparent resin or a translucent resin.

14. The solar cell module as set forth in claim 4, further comprising:
a circuit substrate on which the plurality of solar cells are mounted,
a surface of the circuit substrate and light-receiving surfaces of the plurality of solar cells mounted on the surface of the circuit substrate being encapsulated by at least a transparent resin or a translucent resin.

15. The solar cell module as set forth in claim 5, further comprising:
a circuit substrate on which the plurality of solar cells are mounted,
a surface of the circuit substrate and light-receiving surfaces of the plurality of solar cells mounted on the surface of the circuit substrate being encapsulated by at least a transparent resin or a translucent resin.

16. The solar cell module as set forth in claim 6, further comprising:
a circuit substrate on which the plurality of solar cells are mounted,
a surface of the circuit substrate and light-receiving surfaces of the plurality of solar cells mounted on the surface of the circuit substrate being encapsulated by at least a transparent resin or a translucent resin.

17. A method for manufacturing a solar cell module including a plurality of solar cells, the plurality of solar cells being two-dimensionally arranged, at least one of the plurality of solar cells being positioned on an extended line of a boundary line between solar cells adjacent to the at least one of the plurality of solar cells, the method comprising the step of
encapsulating, with at least a transparent resin or a translucent resin, (i) a surface of a circuit substrate on which the plurality of solar cells are mounted, and (ii) light-receiving surfaces of the plurality of solar cells mounted on the surface of the circuit substrate,
the encapsulating being any one of (I) applying and curing at least the transparent resin or the translucent resin and (II) bonding, by application of heat and pressure, a sheet material made of at least the transparent resin or the translucent resin.
